(19) United States
(12) Patent Application Publication
(10) Pub. No.: US 2023/0173943 A1
(43) Pub. Date: Jun. 8, 2023

(54) CHARGING FUNCTION INSPECTION DEVICE

(71) Applicants: Hyundai Motor Company, Seoul (KR); Kia Corporation, Seoul (KR)

(72) Inventor: Hoo Taeg LEE, Hwaseong-Si (KR)

(73) Assignees: Hyundai Motor Company, Seoul (KR); Kia Corporation, Seoul (KR)

(21) Appl. No.: 17/982,340

(22) Filed: Nov. 7, 2022

(30) Foreign Application Priority Data
Dec. 8, 2021 (KR) 10-2021-0174890

(51) Int. Cl. B60L 58/12; G01R 31/00; B60L 53/16; B60L 53/66; B60L 53/62; B60L 53/30

(52) U.S. Cl. CPC B60L 58/12; G01R 31/007; B60L 53/16; B60L 53/66; B60L 53/62; B60L 53/305

(57) ABSTRACT

A charging function inspection device for eco-friendly vehicles is provided. The charging function inspection device includes an inspection connector connectable to a vehicle to supply a communication signal and a power signal to the vehicle, and an inspection controller configured to determine whether a charging function of a high-voltage battery of the vehicle is operated normally based on the connection of the inspection connector.

### CROSS REFERENCE TO RELATED APPLICATION

The present application claims priority to Korean Patent Application No. 10-2021-0174890, filed on Dec. 8, 2021, the entire contents of which is incorporated herein for all purposes by this reference.

### BACKGROUND OF THE PRESENT DISCLOSURE

### Field of the Present Disclosure

The present disclosure relates to a charging function inspection device for an eco-friendly vehicle.

### Description of Related Art

Electric vehicles are powered by a motor instead of a conventional internal combustion engine, and include a rechargeable high-voltage battery to power the motor. Because the high-voltage battery is a power source for electric vehicles, it is essential to ensure the normal operation of a charging function of the battery.

Therefore, it is being inspected whether the charging function works properly in the production line of electric vehicles. In general, the inspection of the charging function in the production line is performed by determining whether charging has been normally conducted after actually charging batteries of respective vehicles. To inspect the charging function in the production line, a high-voltage substation for power supply is provided in the production line, and the charging inspection is performed through a charging gun used during actual charging.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a charging function inspection device to solve the problem of charging inspection performed in the production line of electric vehicles.

The objective of the present disclosure is not limited to the aforementioned objective, and the other objectives not mentioned may be clearly understood by those with ordinary skill in the art to which the present disclosure pertains (hereinafter “those skilled in the art”) from the following description.

The features of the present disclosure for achieving the objective of the present disclosure, and performing the characteristic functions of the present disclosure to be described later are as follows below.

According to various aspects of the present disclosure, there is provided a charging function inspection device including: an inspection connector connectable to a vehicle to supply a communication signal and a power signal to the vehicle; and an inspection controller configured to determine whether a charging function of a high-voltage battery of the vehicle is normal based on a connection of the inspection connector.

According to an exemplary embodiment of the present disclosure, the charging function inspection device is capable of efficiently performing a charging function inspection of a produced vehicle.

The effects of the present disclosure are not limited to those described above, and other effects not mentioned will be clearly recognized by those skilled in the art from the following description.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a view schematically illustrating the connection between a charging function inspection device and a vehicle according to an exemplary embodiment of the present disclosure;

FIG. 2A and FIG. 2B are views exemplarily illustrating exemplary inspection connectors according to various embodiments of the present disclosure;

FIG. 3 is a view exemplarily illustrating a schematic diagram of a charging function inspection device and a vehicle charging management system of a vehicle according to an exemplary embodiment of the present disclosure;

FIG. 4 is a flowchart illustrating the operation of the charging function inspection device according to an exemplary embodiment of the present disclosure;

FIG. 5 is a view exemplarily illustrating a quick charging inspection mode; and

FIG. 6 is a view exemplarily illustrating a slow charging inspection mode.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Specific structural or functional descriptions presented in exemplary embodiments of the present disclosure are only exemplified for describing the exemplary embodiments according to the concept of the present disclosure, and the exemplary embodiments according to the concept of the present disclosure may be conducted in various forms. Furthermore, the exemplary embodiments of the present disclosure may not be interpreted as being limited to the exemplary embodiments described in the present specification, and should be understood as including all modifications, equivalents, and substitutes included in the spirit and scope of the present disclosure.

Meanwhile, in the present disclosure, terms such as first and/or second may be used to describe various components, but the components are not limited to the terms. The terms are used only for distinguishing one component from other components. For example, a first component may be referred to as a second component, and similarly, the second component may also be referred to as the first component, without departing from the scope according to the concept of the present disclosure.

When a component is referred to as being “connected” or “coupled” to another component, it should be understood that the components may be directly connected or coupled to each other, but still other component may also exist therebetween. On the other hand, when a component is referred to as being “directly connected to” or “in direct contact with” another component, it should be understood that there is no other component therebetween. Other expressions for describing the relationship between components, that is, expressions such as “between” and “directly between” or “adjacent to” and “directly adjacent to” should be also interpreted in the same manner.

Throughout the specification, the same reference numerals refer to the same elements. Meanwhile, the terms used in the present specification are for describing the exemplary embodiments and are not intended to limit the present disclosure. In the present specification, the singular form also includes the plural form unless otherwise specified in the phrase. “Comprises” and/or “comprising” used in the specification specifies the presence of the mentioned component, step, operation, and/or element, and does not exclude the presence or the addition of one or more other components, steps, operations, and/or elements.

Hereinafter, the present disclosure will be described in detail with reference to the accompanying drawings.

As described above, the inspection of a charging function in the production line of vehicles is performed through actual charging. However, there are several problems with the current inspection method.

First, additional costs are incurred. The charging inspection may be conducted only in a limited environment where a high-voltage substation is provided. Accordingly, a high-voltage substation facility is provided in the production line. Accompanying with the present facility, safety-related installations are established. In other words, the current inspection method requires a significant amount of expenditures for the infrastructure. Furthermore, the inspection time for actual charging is excessive, resulting in inspection-related labor costs.

Furthermore, workability is unsatisfactory in that it takes time and effort to perform the inspection. The charging function is currently checked by use of an actual charging gun. In case of quick charging, the weight of the charging gun is high and the charging cable is thick, which makes difficult for an operator to perform the inspection.

Accordingly, the present disclosure is directed to providing a charging function inspection device configured for reducing the time and cost associated with the charging function inspection and improving the operator's workability and convenience.

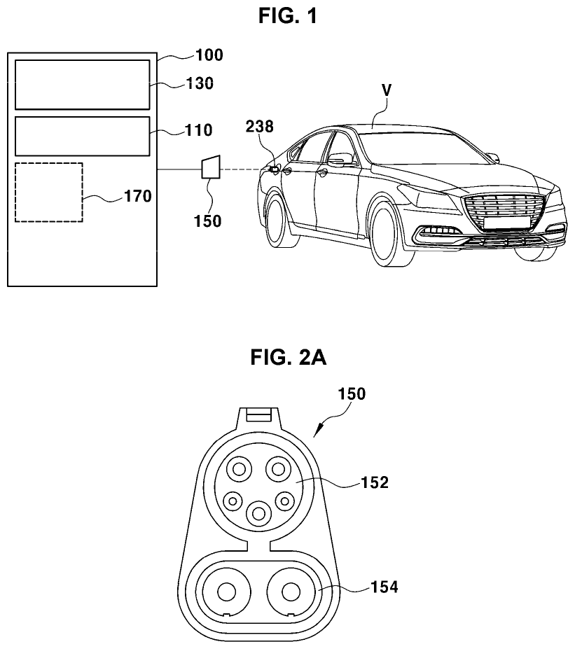

As illustrated in FIG. 1, a charging function inspection device 100 for a vehicle according to an exemplary embodiment of the present disclosure includes an input unit 110, an output unit 130, an inspection connector 150, and an inspection controller 170. Here, a vehicle V may include eco-friendly vehicles, such as a plug-in hybrid electric vehicle including a rechargeable high-voltage battery, as well as an electric vehicle.

The input unit 110 and the output unit 130 are configured to communicate with the operator of the charging function inspection device 100. The operator may make inspection-related settings, such as starting of the inspection, through the input unit 110. The output unit 130 is configured to display an inspection status based at least in part on the inspection-related settings. In an implementation, the input unit 110 may include an input device, such as a manipulation panel, a keyboard, or the like. In an implementation, the output unit 130 may include a display device, such as a monitor.

The charging function inspection device 100 includes one or more inspection connectors 150. The inspection connector 150 connects the vehicle V to be tested with the charging function inspection device 100. The inspection connector 150 may be connected to a charging port 238 of the vehicle V. In an implementation, the inspection connector 150 may provide an actual charging current for slow charging.

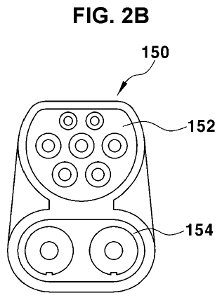

In an implementation, the inspection connector 150 is integrated with a connector for a slow charging inspection and a connector for a quick charging inspection. For example, as illustrated in FIG. 2A and FIG. 2B, a first portion 152 which is a portion for the slow charging inspection and a second portion 154 which is a portion for the quick charging inspection may be integrated into a single inspection connector 150. For the present reason, according to an exemplary embodiment of the present disclosure, one-time connection of the inspection connector 150 allows determination of the quick charging and slow charging operations together, increasing the convenience of inspection.

The inspection controller 170 manages control of the charging function inspection device 100. Furthermore, the inspection controller 170 is configured to communicate with the vehicle V. The inspection controller 170 may be configured to communicate with a vehicle charging management system 200 of the vehicle V. The inspection controller 170 may inspect whether both the quick charging function and the slow charging function of the vehicle V operate normally through cooperation with the vehicle charging management system 200.

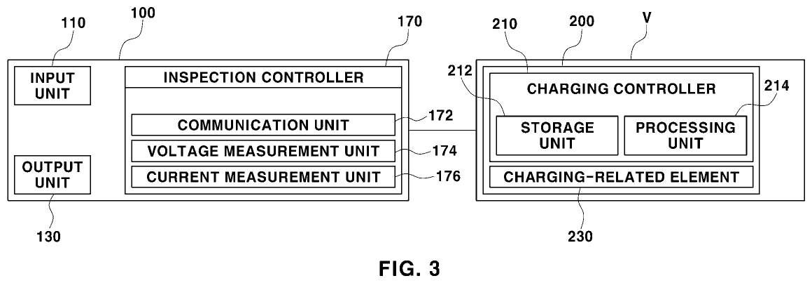

As illustrated in FIG. 3, according to an implementation of the present disclosure, the inspection controller 170 includes a communication unit 172, a voltage measurement unit 174, and a current measurement unit 176.

The communication unit 172 is configured to communicate with the vehicle charging management system 200. In an implementation, a processing unit 214 processes a signal requesting a charging function inspection from the operator through the input unit 110. The operator inputs the inspection request signal for the vehicle V through the input unit 110, and the communication unit 172 transmits the inspection request signal to the charging controller 210 of the vehicle V. Here, the inspection request signal transmitted to the vehicle V may cause the vehicle charging management system 200 to recognize the inspection situation rather than the actual charging situation. As a non-limiting example, upon the connection of the inspection connector 150, the vehicle V may recognize the connection of the inspection connector 150 through a preset resistance value.

The vehicle charging management system 200, in particular, the charging controller 210 of the vehicle charging management system 200 is configured to receive the inspection request signal from the charging function inspection device 100 and to inspect a charging function based on the received signal. In an implementation, the vehicle charging management system 200 is configured to control the charging function of the vehicle. The charging controller 210 may manage the charging of a high-voltage battery 232 and control the vehicle charging management system 200 of the vehicle V to inspect the charging function. To the present end, according to an implementation of the present disclosure, the charge controller 210 may include a storage unit 212 and a processing unit 214.

The storage unit 212 may store a series of commands to be executed when the charging function inspection is performed. When the inspection request signal is received from the inspection controller 170, a series of commands to be performed by the processing unit 214 may be stored in the storage unit 212. In an implementation, the storage unit 212 includes an execution command for a quick charging inspection mode and an execution command for a slow charging inspection mode. In an implementation, the storage unit 212 may also be provided in the inspection controller 170. That is, commands stored in the storage unit 212 may be transmitted to the processing unit 212 whenever the inspection mode is executed. However, in the present specification, for a unified description, the storage unit 212 for storing a series of inspection-related commands will be referred to as being provided in the vehicle charging management system 200.

When the inspection request signal is received from the charging function inspection device 100, the processing unit 214 is configured to perform the charging function inspection based on a series of commands stored in the storage unit 212. In an implementation, the processing unit 214 controls a charging-related element 230 in the vehicle V so that the charging function is inspected. The charging-related element 230 is a charging-related component disposed in a charging circuit in the vehicle V, which may include a high-voltage battery 232, an on-board charger 234, a high-voltage junction box 236, a charging port 238, and certain relays and connectors.

In the charging function inspection mode stored in the storage unit 212, it is determined whether the charging function operates normally, such as whether the charging-related element 230 operates normally or there is no problem in the connection. For example, in the quick charging inspection mode, it may be determined whether the parts related to the quick charging of the high-voltage battery 232 are properly connected. In the slow charging inspection mode, it may be determined whether the charging-related element 230 has been fused or damaged. The normal operation of the charging function may be determined by the voltage measurement by the voltage measuring unit 174 of the charging function inspection device 100 for each inspection mode, which will be described in detail below.

Hereinafter, the operation of the charging function inspection device 100 according to an exemplary embodiment of the present disclosure will be described.

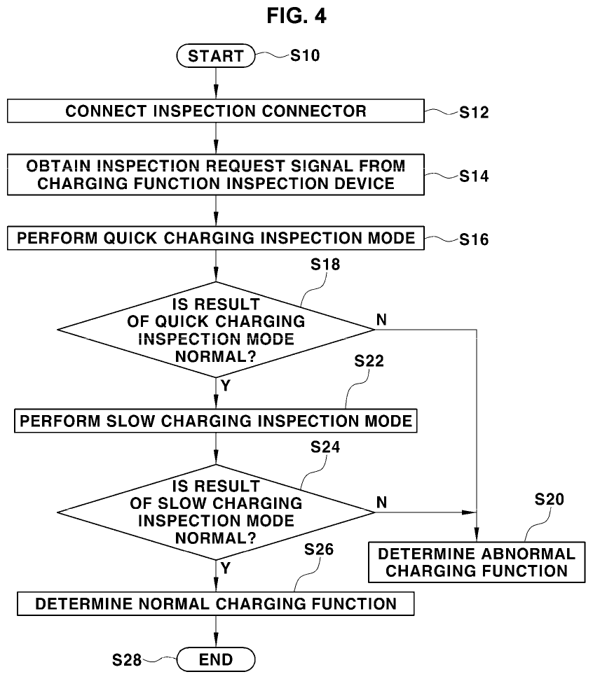

Referring to FIG. 4, the inspection process of the charging function inspection device 100 starts in step S10.

The inspection connector 150 of the charging function inspection device 100 is connected to the charging port 238 of the vehicle V (S12). In an implementation, the inspection controller 170 and the charge controller 210 may exchange communication signals through the connection between the inspection connector 150 and the charging port 238.

Furthermore, when the inspection request signal is input from the operator through the input unit 110, the communication unit 172 of the charging function inspection device 100 transmits the inspection request signal to the charging controller 210 (S14). The inspection request signal causes the charging controller 210 to recognize that the current situation is an inspection status rather than a charging status, and the charging controller 210 enters an inspection mode according to a command stored in the storage unit 212. In an implementation, a notification indicating that the inspection has started may be displayed on the output unit 130.

As described above, the first portion 152 for a slow charging inspection and the second portion 154 for a quick charging inspection are integrated into the inspection connector 150. For the present reason, according to an exemplary embodiment of the present disclosure, it is possible to determine whether the quick charging and slow charging functions operate normally through one connection between the inspection device 100 and the vehicle V through the inspection connector 150. Furthermore, quick charging inspection and slow charging inspection may be performed through signal processing in the charging function inspection device 100.

Upon entering the inspection mode, the quick charging inspection mode is executed in step S16. In an implementation, when entering the inspection mode, the quick charging inspection mode may be automatically executed. In another implementation, the quick charging inspection mode may be requested through the input unit 110 by the operator, and the operator's selection is transmitted to the charging controller 210 through the communication unit 172, whereby the quick charging inspection mode may then be executed.

When the quick charging inspection mode is executed, the processing unit 214 causes the inspection to be implemented according to a command for performing the quick charging inspection mode stored in the storage unit 212. The quick charging inspection mode may include a first mode and a second mode. In an implementation, a notification indicating that the quick charging inspection mode is running may be displayed on the output unit 130.

In the first mode, the charging controller 210 or the processing unit 214 forcibly activates the charging-related element 230 for the quick charging, and then releases the forced activation. All relays are turned OFF. Then the voltage measurement unit 174 measures a voltage of the high-voltage battery 232.

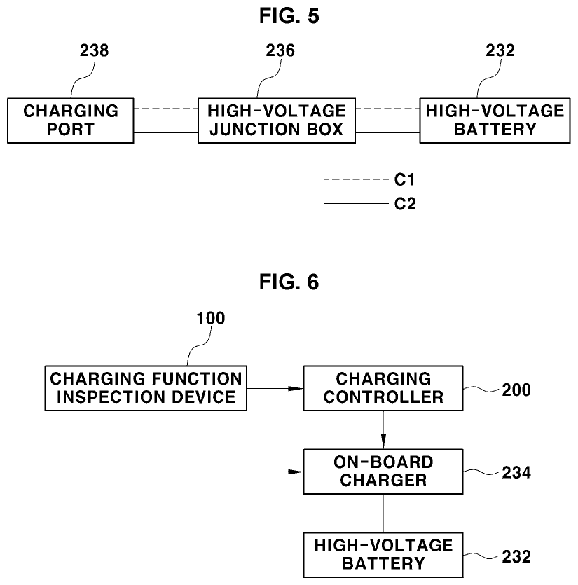

As illustrated in FIG. 5, when the forced activation is canceled, the high-voltage battery 232 is not connected to the charging port 238 (indicated by C1), so in the first mode, 0 volt (V) should be measured during the measurement of the high voltage. When 0V is not measured, it may be determined that the charging-related element 230 for the quick charging has been damaged.

Accordingly, it may be determined whether the quick charging path is normally set up through the ON/OFF operation. This is because, when the parts are damaged or defective, the turn-off operation cannot be performed due to the parts being fused through the high voltage. According to an exemplary embodiment of the present disclosure, the charging-related element 230 is forcedly activated so that respective element is connected or is in association even when not in a charging situation. Accordingly, it is possible to verify the normal operation of the charging-related element 230 and ensure the connectivity of the entire circuit, detecting assembly errors which may occur during assembly.

In the second mode, the processing unit 214 switches the charging-related element 230 for the quick charging to an ON state. In the instant case, as in C2 of FIG. 5, the high-voltage battery 232 is connected to the charging port 238. When the charging-related element 230 is adequately assembled, the voltage of the high-voltage battery 232 may be measured at the charging port 238, and the voltage measurement unit 174 may measure the voltage to determine whether there is an error. That is, if the voltage of the high-voltage battery 232 is not measured, it may be determined that the operation related to the quick charging circuit is omitted or malfunctions.

The voltage measurement in the first mode and the second mode may be performed by the voltage measurement unit 174 of the inspection controller 170. In an implementation, the second portion 154 of the inspection connector 150, i.e., the portion for the quick charging inspection, may be configured to be connected to the voltage measurement unit 174 so that the voltage measurement unit 174 measures the voltage of the second portion 154. Accordingly, the charging function inspection device 100 may determine whether the quick charging is normally functioning based on the measured value by the voltage measurement unit 174 (S18).

Referring back to FIG. 4, if the results of the quick charging inspection mode including the first mode and the second mode are normal, the process proceeds to step S22. On the other hand, if any one of the first mode and the second mode is abnormal, the process proceeds to step S20. If it is determined that any one of the first mode and the second mode is abnormal, the charging function inspection device 100 may determine that the charging function of the tested vehicle is abnormal (S20), and measures may be taken to address the issue.

When it is determined that the result of the quick charging inspection mode is normal, the slow charging inspection mode for the corresponding vehicle is executed (S22). In an implementation, the slow charging inspection mode may be automatically executed after the end of the quick charging inspection mode. In another implementation, the slow charging inspection mode may be executed in response to an operator's request for the slow charging inspection through the input unit 110. In an implementation, the state in which the slow charging inspection mode is performed may be displayed through the output unit 130.

Upon entering the slow charging inspection mode automatically or by request, the charging controller 210 or the processing unit 214 performs the inspection based on the command for the slow charging inspection mode stored in the storage unit 212. As illustrated in FIG. 6, according to an exemplary embodiment of the present disclosure, in the slow charging inspection mode, it is determined whether the slow charging operates normally through actual charging.

In the slow charging inspection mode, the charging current is supplied through the first portion 152 of the inspection connector 150, and the charging controller 210 is configured to control the on-board charger 234 in the vehicle V to actually charge the high-voltage battery 232. According to an exemplary embodiment of the present disclosure, in the slow charging inspection mode, the connectivity of the charging path and the operation of the components may be determined through actual charging.

In an implementation, the slow charging by the inspection connector 150 may be automatically performed by transmitting a slow charging entering signal from the charging function inspection device 100 without replacing the inspection connector 150. For example, the slow charging entering signal may be a pulse width modulation (PWM) input signal, and the inspection controller 170 is configured to transmit such input signal.

Referring back to FIG. 4, the inspection controller 170 determines whether the slow charging is normally performed (S24). When it is confirmed that the slow charging has started after the receipt of the slow charging entering signal, the charging controller 210 notifies the charging function inspection device 100 that the slow charging has started. If this notification is not received from the charging controller 210, the inspection controller 170 determines that there is an issue in the slow charging function. The charging current being input to the vehicle V through the first portion 152 of the inspection connector 150 may be measured, and based on the measured charging current, the inspection controller 170 may determine whether the slow charging is normally performed.

When the result is normal, the inspection controller 170 determines that the charging function of the tested vehicle is normal (S26), and the inspection process ends (S28). On the other hand, if the result is not normal, that is, when a notification indicating the slow charging start is not received from the charging controller 210 or the measured charging current is not normal, the inspection controller 170 determines that the charging function of the target vehicle is abnormal (S20).

In an implementation, the slow charging inspection mode may be performed after the quick charging inspection mode is performed. According to another implementation, the quick charging inspection mode may be performed after the slow charging inspection mode is performed. That is, either of these inspection performance sequences is possible. Although it has been described herein that the quick charging inspection is performed before the slow charging inspection, the slow charging inspection may be performed prior to the quick charging inspection.

The charging function inspection device according to an exemplary embodiment of the present disclosure can reduce the cost related to the high-voltage substation facility for the charging function inspection in the vehicle production line and the related safety equipment.

The charging function inspection device according to an exemplary embodiment of the present disclosure can reduce labor costs through the reduction in the number of processes performed by an operator.

The charging function inspection device according to an exemplary embodiment of the present disclosure may be used anywhere a general commercial voltage is supplied, which increases the degree of freedom in process organization and design.

The charging function inspection device according to an exemplary embodiment of the present disclosure can improve production efficiency by reducing the inspection time required for the existing charging inspection.

The charging function inspection device according to an exemplary embodiment of the present disclosure can reduce the possibility of the operator's injury by reducing the weight of the charging connector (inspection connector) and promote the operator's workability and convenience.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by multiple control devices, or an integrated single control device.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A charging function inspection apparatus comprising:
an inspection connector connectable to a vehicle to supply a communication signal and a power signal to the vehicle; and
an inspection controller configured to determine whether a charging function of a battery of the vehicle is normal based on a connection of the inspection connector.

2. The charging function inspection apparatus of claim 1, wherein the inspection controller is configured to communicate with a vehicle charging management system including a charging controller operatively controlling a charging-related element of the vehicle and communicable with the inspection controller.

3. The charging function inspection apparatus of claim 1, wherein the inspection connector is connected to a charging port of the vehicle for charging the battery.

4. The charging function inspection apparatus of claim 1, further including:
an input unit of inputting an inspection-related request to the inspection controller; and
an output unit of displaying an inspection state implemented according to the request.

5. The charging function inspection apparatus of claim 2, wherein the inspection controller is configured to:
transmit an inspection request to the charging controller;
control the charging controller to execute a first inspection operation which is one of a quick charging inspection operation and a slow charging inspection operation of the battery; and
in response to determining that the first inspection operation is normal, control the charging controller to execute a second inspection operation which is the other of the quick charging inspection operation and the slow charging inspection operation.

6. The charging function inspection apparatus of claim 5, wherein the first inspection operation is the quick charging inspection operation, and the second inspection operation is the slow charging inspection operation.

7. The charging function inspection apparatus of claim 6, wherein during the first inspection operation, the inspection controller is configured to:
control the charging controller to turn off the charge-related element after forced activation of the charge-related element; and
determine whether a quick charging function operates normally based on a voltage of the battery measured after the turn-off operation.

8. The charging function inspection apparatus of claim 7, wherein the inspection controller is configured to measure the voltage of the battery through the inspection connector.

9. The charging function inspection apparatus of claim 6, wherein during the second inspection operation, the inspection controller is configured to:
control the charging controller to execute slow charging; and
determine whether a slow charging function operates normally in accordance with initiation of the slow charging.

10. The charging function inspection apparatus of claim 9, wherein the inspection controller is configured to:
measure a charging current of the battery through the inspection connector; and
determine whether the slow charging function operates normally based on the charging current.

11. The charging function inspection apparatus of claim 8, wherein the inspection controller includes a voltage measurement unit configured to measure the voltage of the battery through a quick charging portion for the quick charging function inspection formed in the inspection connector.

12. The charging function inspection apparatus of claim 10, wherein the inspection controller includes a current measurement unit configured to measure the charging current through a slow charging portion for the slow charging function inspection formed in the inspection connector.

13. The charging function inspection apparatus of claim 7, wherein the inspection controller is configured to:
after the turn-off operation, control the charging controller to forcedly re-activate the charging-related element; and
determine whether the quick charging function operates normally based on the voltage of the battery measured after the forced activation.

14. The charging function inspection apparatus of claim 2, wherein the charging-related element includes parts forming a charging circuit for charging the battery of the vehicle.

15. The charging function inspection apparatus of claim 3, wherein the inspection connector is integrated with a quick charging inspection connector portion for quick charging function inspection of the battery and a slow charging inspection connector portion for slow charging function inspection of the battery.
